(19) United States
(12) Patent Application Publication
(10) Pub. No.: US 2025/0059388 A1
(43) Pub. Date: Feb. 20, 2025

(54) COMPOSITION FOR FORMING COLORED LAYER, OPTICAL FILM AND DISPLAY DEVICE

(71) Applicant: Toppan Holdings Inc., Tokyo (JP)

(72) Inventors: Kai FUTAMATA, Tokyo (JP); Yoshiko Ishimaru, Tokyo (JP); Shinya Ishikawa, Tokyo (JP)

(73) Assignee: Toppan Holdings Inc., Tokyo (JP)

(21) Appl. No.: 18/936,412

(22) Filed: Nov. 4, 2024

Related U.S. Application Data
(63) Continuation of application No. PCT/JP2023/016150, filed on Apr. 24, 2023.

(30) Foreign Application Priority Data
May 11, 2022 (JP) 2022-078418

(51) Int. Cl. C09D 7/41; C08K 5/00; C08K 5/5397; C09D 7/48; C09D 133/14; G02B 1/16; G02B 1/18; G02B 5/22; G02B 5/28

(52) U.S. Cl. CPC C09D 7/41; C08K 5/0041; C08K 5/0091; C08K 5/5397; C09D 7/48; C09D 133/14; G02B 1/16; G02B 1/18; G02B 5/223; G02B 5/283

(57) ABSTRACT

A composition for forming a colored layer contains a dye, an active energy radiation-curable resin, a photoinitiator, a solvent, and an additive. The dye contains at least one of a first coloring material, a second coloring material, and a third coloring material, with the wavelength of maximum absorption within the range of 470 to 530 nm and the full width at half maximum of the absorption spectrum is 15 to 45 nm. The wavelength of maximum absorption of the second coloring material is within the range of 560 to 620 nm and the full width at half maximum of the absorption spectrum is 15 to 55 nm. Within the wavelength range of 380 to 780 nm, the third coloring material exhibits the lowest transmittance in the range of 650 to 780 nm. The additive includes a compound A and a sulfur antioxidant.

### CROSS-REFERENCE TO RELATED PATENT APPLICATIONS

This application is a continuation application filed under 35 U.S.C. § 111(a) claiming the benefit under 35 U.S.C. §§ 120 and 365(c) of International Patent Application No. PCT/JP2023/016150, filed on Apr. 24, 2023, which is based upon and claims the benefit to Japanese Patent Application No. 2022-078418, filed on May 11, 2022, the disclosures of all which are incorporated herein by reference in their entirety.

### TECHNICAL FIELD

The present invention relates to a composition for forming a colored layer, an optical film, and a display device.

### BACKGROUND

Display devices are often used in environments where there is incident external light, whether indoors or outdoors. The external light incident on the display device is reflected at the surface of the display device, causing a reduction in display quality. In particular, self-emissive display devices such as organic light-emitting display devices have the problem that the electrodes and many other metal wirings strongly reflect external light, which tend to degrade display quality, but are expected to become next-generation display devices because of their superior characteristics such as the ability to reduce size, low power consumption, high luminance, and high response speed.

There is a configuration in which a polarizing plate and a retarder are placed on the display surface side to suppress reflection of external light and thereby solve the problem of drop in display quality due to reflection of external light.

However, in the method using a polarizing plate and a retarder, when the light from the display device passes through the polarizing plate and retarder to be emitted to the outside, a considerable portion of the light is lost. This has tended to reduce the lifespan of the device.

PTL 1 proposes an organic light-emitting display device having a display substrate including organic light-emitting elements and a sealing substrate placed apart from the display substrate. A filler is embedded in the space between the display substrate and the sealing substrate to adjust the transmittance by selectively absorbing external light in one or more specific wavelength bands. According to the invention of PTL 1, in addition to the improvement in visibility achieved by suppressing external light reflection, the color purity is improved because the portion of the light emitted from the display device that is in a wavelength band that particularly reduces color purity is selectively absorbed.

Regarding the improvement in color purity, PTL 2 discloses a configuration containing a dye having maximum absorption wavelengths at least in the wavelength regions 480 to 510 nm and 580 to 610 nm.

### CITATION LIST

### Patent Literature

[PTL 1] JP 5673713 B;

[PTL 2] JP 2019-56865 A;

[PTL 3] WO 2021/066082 A.

### SUMMARY OF THE INVENTION

### Technical Problem

Many wavelength selective absorption dyes have low light resistance and low heat resistance, and may not be able to fully exhibit the effect of improving color purity when their function deteriorates over time.

In relation to this problem, PTL 3 discloses a configuration in which a specific compound is added to a dye as an anti-fading agent, and a gas barrier layer is provided. However, the gas barrier layer causes increase in film thickness and cost, and the dye may deteriorate from parts where the gas barrier layer is not provided. Furthermore, the inventors have found that when only the anti-fading agent is added without providing the gas barrier layer, the light resistance improves but the heat resistance decreases.

In view of the above circumstances, an object of the present invention is to provide a composition for forming a colored layer capable of forming a colored layer that can withstand long-term use without requiring a gas barrier layer.

Another object of the present invention is to provide an optical film and a display device that can maintain high display quality even when used for a long period of time without requiring a gas barrier layer.

### Solution to Problem

A first aspect of the present invention is a composition for forming a colored layer containing a dye (A), an active energy radiation-curable resin (B), a photoinitiator (C), a solvent (D), and an additive (E).

The dye (A) contains at least one of a first coloring material, a second coloring material, and a third coloring material. The wavelength of maximum absorption of the first coloring material is within the range of 470 to 530 nm, and the full width at half maximum of the absorption spectrum is 15 to 45 nm. The wavelength of maximum absorption of the second coloring material is within the range of 560 to 620 nm, and the full width at half maximum of the absorption spectrum is 15 to 55 nm. Within the wavelength range of 380 to 780 nm, the third coloring material exhibits the lowest transmittance in the range of 650 to 780 nm.

The additive (E) includes a compound A represented by formula (i) below and a sulfur antioxidant, and the content of the compound A is 0.01 to 2 when the content of the sulfur antioxidant is taken as 1.

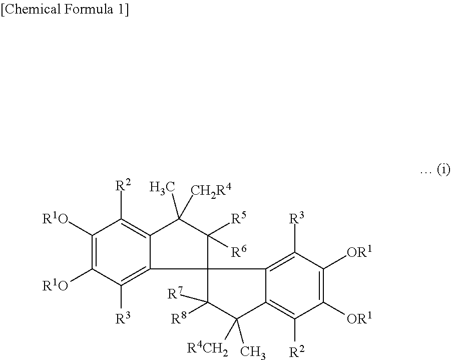

In formula (i), each R¹ independently represents an alkyl group, an alkenyl group, an aryl group, a heterocyclic group, or R⁹CO—, R¹⁰SO₂—, or R¹¹NHCO—. R⁹, R¹⁰, and R¹¹ are each independently an alkyl group, an alkenyl group, an aryl group, or a heterocyclic group. R² and R³ each independently represent a hydrogen atom, a halogen atom, an alkyl group, an alkenyl group, an alkoxy group, or an alkenyloxy group. R⁴ to R⁸ each independently represent a hydrogen atom, an alkyl group, an alkenyl group, or an aryl group.

A second aspect of the present invention is an optical film including a colored layer that is a cured product of the composition for forming the colored layer according to the first aspect; a transparent substrate located on one surface of the colored layer; and a functional layer located on the one or the other surface of the colored layer.

One or both of the transparent substrate and the functional layer have an ultraviolet shielding rate of 85% or higher as measured according to a method described in JIS L 1925. The functional layer functions as an antireflection layer or an antiglare layer.

A third aspect of the present invention is a display device including the optical film according to the second aspect.

### Advantageous Effects of the Invention

According to the present invention, a composition can be provided for forming a colored layer capable of forming a colored layer that can withstand long-term use without requiring a gas barrier layer.

Further, according to the present invention, it is also possible to provide an optical film and a display device that can maintain high display quality even when used for a long period of time without requiring a gas barrier layer.

### BRIEF DESCRIPTION OF THE DRAWINGS

FIG. 1 is a cross-sectional view of an optical film according to an embodiment of the invention.

FIG. 2 is a cross-sectional view of an optical film according to another aspect of the invention.

FIG. 3 is a cross-sectional view of an optical film according to another aspect of the invention.

FIG. 4 is a cross-sectional view of an optical film according to another aspect of the invention.

FIG. 5 is a cross-sectional view of an optical film according to another aspect of the invention.

FIG. 6 is a cross-sectional view of an optical film according to another aspect of the invention.

FIG. 7 is a graph showing the spectrum of a white mode output through an organic EL light source and a color filter in Examples.

FIG. 8 is a graph showing the spectra during red, green, and blue output modes through the organic EL light source and color filter in the Examples.

### DETAILED DESCRIPTION

With reference to the drawings, some embodiments of the present invention will be described. Throughout the drawings, the same reference signs are given to the same or corresponding components between different embodiments to omit duplicate description.

### Optical Film

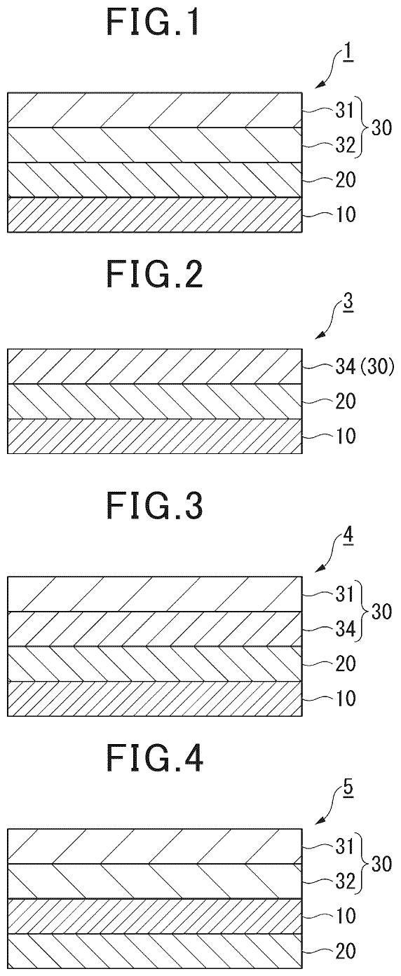

Referring to FIG. 1, an optical film according to an embodiment of the present invention will be described in detail.

As shown in FIG. 1, the optical film 1 includes a colored layer 10, a transparent substrate 20, and a functional layer 30. The functional layer 30 includes a low refractive index layer 31 and a hard coat layer 32. That is, the optical film 1 has the transparent substrate 20 located on one surface of the colored layer 10 and is a laminate in which the colored layer 10, the transparent substrate 20, the hard coat layer 32, and the low refractive index layer 31 are laminated in this order.

The thickness of the optical film 1 is, for example, preferably in a range of 10 to 140 μm, more preferably 15 to 120 μm, and still more preferably 20 to 100 μm. When the thickness of the optical film 1 is equal to or larger than this lower limit, the strength of the optical film 1 can be further increased. When the thickness of the optical film 1 is equal to or smaller than the above upper limit, not only the optical film 1 can be more lightweight but also the display device can be thinner.

The following description addresses the individual layers forming the optical film 1.

### Colored Layer

The colored layer 10 is obtained by curing the composition for forming a colored layer of the present invention. The composition for forming a colored layer of the present invention contains a dye (A), an active energy radiation-curable resin (B), a photoinitiator (C), a solvent (D), and an additive (E).

The thickness of the colored layer 10 is preferably 0.5 to 10 μm, for example. When the thickness of the colored layer 10 is equal to or greater than the lower limit, the colored layer 10 can contain a dye without causing any abnormality in appearance, and the light absorption by the dye improves reflection characteristics and color reproducibility. When the thickness of the colored layer 10 is equal to or smaller than the above upper limit, it is advantageous in making the display device thinner.

The thickness of the colored layer 10 is determined by observing the cross section of the optical film 1 in the thickness direction (cross section as viewed in a direction intersecting the thickness direction) using a microscope or the like.

### Dye (A)

The dye (A) contains at least one of a first coloring material, a second coloring material, and a third coloring material described below.

The wavelength of maximum absorption of the first coloring material is within the range of 470 to 530 nm, and the full width at half maximum of the absorption spectrum is 15 to 45 nm. When the wavelength of maximum absorption is lower than the lower limit, the luminance efficiency for blue light emission is likely to decrease, and when it exceeds the upper limit, the luminance efficiency for green light emission is likely to decrease. When the full width at half maximum of the absorption spectrum is lower than the lower limit, the effect of suppressing external light reflection is reduced. On the other hand, when it exceeds the upper limit, the external light reflection characteristics tend to improve but the luminance efficiency is likely to decrease.

The wavelength of maximum absorption of the second coloring material is within the range of 560 to 620 nm, and the full width at half maximum of the absorption spectrum is 15 to 55 nm. When the wavelength of maximum absorption is lower than the lower limit, the luminance efficiency for green light emission is likely to decrease, and when it exceeds the upper limit, the luminance efficiency for red light emission is likely to decrease. When the full width at half maximum of the absorption spectrum is lower than the lower limit, the effect of suppressing external light reflection is reduced. On the other hand, when it exceeds the upper limit, the external light reflection characteristics tend to improve but the luminance efficiency is likely to decrease.

Within the wavelength range of 380 to 780 nm, the third coloring material exhibits the lowest transmittance in the range of 650 to 780 nm. When the wavelength at which the transmittance of the third coloring material is lowest within the wavelength range of 380 to 780 nm is lower than the lower limit, the luminance efficiency for red light emission is likely to decrease, and when it exceeds the upper limit, the effect of suppressing external light reflection decreases.

The dye (A) preferably contains a compound having a porphyrin structure, merocyanine structure, phthalocyanine structure, azo structure, cyanine structure, squarylium structure, coumarin structure, polyene structure, quinone structure, tetradiporphyrin structure, pyrromethene structure, or indigo structure; or a metal complex thereof. In other words, the dye (A) preferably contains one or more selected from the group consisting of compounds having a porphyrin structure, merocyanine structure, phthalocyanine structure, azo structure, cyanine structure, squarylium structure, coumarin structure, polyene structure, quinone structure, tetradiporphyrin structure, pyrromethene structure, and indigo structure; and a metal complex thereof.

In particular, it is more preferable to use a metal complex having a porphyrin structure, pyrromethene structure, or phthalocyanine structure, or a compound having a squarylium structure because of their high stability. The dye (A) may contain only one of these compounds or metal complexes thereof, or two or more of them. These compounds or metal complexes thereof may be contained in the first, second, or third coloring material, or in two or more of these coloring materials.

### Active Energy Radiation-Curable Resin (B)

The active energy radiation-curable resin (B) is a resin that is cured by irradiating the resin with active energy radiation such as ultraviolet light or electron beams for polymerization. For example, monofunctional, bifunctional, or trifunctional (meth)acrylate monomers or urethane (meth)acrylates, or those with more functional groups can be used, but the active energy radiation-curable resin (B) of the present invention includes a resin that at least has the ability to scavenge radicals (radical scavenging ability). Here, “(meth)acrylate” means one or both of “acrylate” and “methacrylate”.

An example of a resin having radical scavenging ability included in the active energy radiation-curable resin (B) is a resin having an amine structure. The “amine structure” refers to a structure in which the hydrogen atom of ammonia is replaced with a hydrocarbon group or an aromatic group. Examples of the amine structure include primary amine, secondary amine, and tertiary amine. It may also be a quaternary ammonium cation.

The radical scavenging resin suppresses dye deterioration (fading) by scavenging radicals and suppressing autooxidation when the dye (A) undergoes oxidative deterioration. An example of a resin having a radical scavenging amine structure is a resin having a hindered amine structure and a molecular weight of 2000 or higher. When the molecular weight of the resin having a hindered amine structure is 2000 or higher, the effect of suppressing fading can be improved. This is considered to be because many molecules remain in the colored layer 10, and thus a sufficient effect of suppressing fading can be obtained.

The upper limit of the molecular weight of the resin having a hindered amine structure is, for example, about 200,000, but the upper limit is not particularly limited.

The term “molecular weight” as used herein means “mass average molecular weight” measured by gel permeation chromatography (GPC) using polystyrene as the standard substance.

In this embodiment, the resin having a radical scavenging amine structure preferably has a structural unit represented by the following formula (ii).

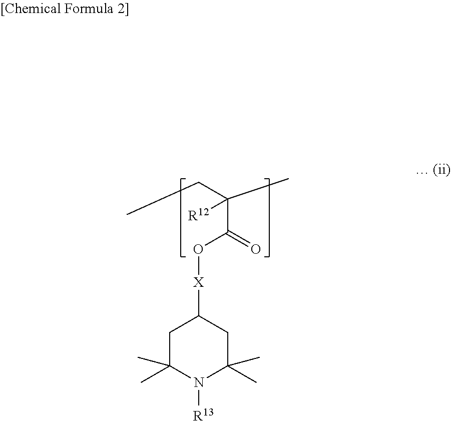

In the above formula (ii), R¹² represents a hydrogen atom, halogen atom, carboxyl group, sulfo group, cyano group, hydroxy group, alkyl group having 10 or less carbon atoms, alkoxycarbonyl group having 10 or less carbon atoms, alkylsulfonylaminocarbonyl group having 10 or less carbon atoms, arylsulfonylaminocarbonyl group, alkylsulfonyl group, arylsulfonyl group, acylaminosulfonyl group having 10 or less carbon atoms, alkoxy group having 10 or less carbon atoms, alkylthio group having 10 or less carbon atoms, aryloxy group having 10 or less carbon atoms, nitro group, alkoxycarbonyloxy group, aryloxycarbonyloxy group, acyloxy group having 10 or less carbon atoms, acyl group having 10 or less carbon atoms, carbamoyl group, sulfamoyl group, aryl group having 10 or less carbon atoms, substituted amino group, substituted ureido group, substituted phosphono group, or a heterocyclic group. R¹³ represents a hydrogen atom or an alkyl group having 30 or less carbon atoms. X represents a single bond, an ester group, an aliphatic alkyl chain having 30 or less carbon atoms, an aromatic chain, a polyethylene glycol chain, or a linking group formed by combination thereof. Any of R¹², R¹³, and X may contain a spirodioxane ring.

R¹² is preferably a hydrogen atom, a hydroxy group, or an alkyl group having 10 or less carbon atoms. The number of carbon atoms in the alkyl group is preferably 1 to 6, more preferably 1 to 3.

R¹³ is preferably a hydrogen atom or an alkyl group having 10 or less carbon atoms. The number of carbon atoms in the alkyl group is preferably 1 to 6, more preferably 1 to 3.

X is preferably a single bond or an aliphatic alkyl chain having 30 or less carbon atoms. The number of carbon atoms in the aliphatic alkyl chain is preferably 10 to less, preferably 1 to 6, more preferably 2 to 4.

In this embodiment, the main component (the component with the highest mass %) of the resin having a radical scavenging amine structure is a copolymer of the structural unit represented by the above formula (ii) and a copolymer component having one of the following repeating units. A copolymer can control compatibility with other components.

Examples of the repeating units include (meth)acrylate repeating units, olefin repeating units, halogen atom-containing repeating units, styrene repeating units, vinyl acetate repeating units, and vinyl alcohol repeating units.

Examples of (meth)acrylate repeating units include repeating units derived from (meth)acrylate monomers having a linear or branched alkyl group in their side chains, and repeating units derived from (meth)acrylate monomers having a hydroxyl group in their side chains.

Examples of the repeating units derived from (meth)acrylate monomers having a linear or branched alkyl group in their side chains include components derived from monomers such as methyl (meth)acrylate, ethyl (meth)acrylate, propyl (meth)acrylate, isopropyl (meth)acrylate, butyl (meth)acrylate, isobutyl (meth)acrylate, s-butyl (meth)acrylate, t-butyl (meth)acrylate, pentyl (meth)acrylate, hexyl (meth)acrylate, heptyl (meth)acrylate, octyl (meth)acrylate, isooctyl (meth)acrylate, 2-ethylhexyl acrylate, nonyl (meth)acrylate, isononyl (meth)acrylate, decyl (meth)acrylate, isodecyl (meth)acrylate, undecyl (meth)acrylate, dodecyl (meth)acrylate, tridecyl (meth)acrylate, tetradecyl (meth)acrylate, myristyl (meth)acrylate, pentadecyl (meth)acrylate, hexadecyl (meth)acrylate, heptadecyl (meth)acrylate, and octadecyl (meth)acrylate. These may be used alone or in combination of two or more thereof. Among the above examples, (meth)acrylate repeating units having a linear or branched alkyl group with 1 to 4 carbon atoms in their side chains are preferable.

Examples of the repeating units derived from (meth)acrylic monomers having a hydroxyl group in their side chains include components derived from monomers such as 2-hydroxyethyl (meth)acrylate, 2-hydroxypropyl (meth)acrylate, 4-hydroxybutyl (meth)acrylate, 6-hydroxyhexyl (meth)acrylate, and hydroxyphenyl (meth)acrylate. These may be used alone or in combination of two or more.

Examples of olefinic repeating units include components derived from olefinic monomers such as ethylene, propylene, isoprene, and butadiene. These may be used alone or in combination of two or more.

Examples of halogen atom-containing repeating units include components derived from monomers such as vinyl chloride and vinylidene chloride. These may be used alone or in combination of two or more.

Examples of styrene repeating units include components derived from styrene monomers such as styrene, a-methylstyrene, and vinyltoluene. These may be used alone or in combination of two or more.

Examples of vinyl acetate repeating units include esters of saturated carboxylic acids and vinyl alcohol such as vinyl acetate and vinyl propionate. These may be used alone or in combination of two or more.

An example of a vinyl alcohol repeating unit is vinyl alcohol, and it may have a 1,2-glycol bond in its side chain.

The copolymer may have the structure of a random copolymer, alternating copolymer, block copolymer or graft copolymer. The manufacturing process and preparation with other components are easy when the copolymer has the structure of a random copolymer. Therefore, a random copolymer is preferred to the other copolymers.

Radical polymerization may be used as the polymerization method for obtaining the copolymer. Radical polymerization is preferable because it facilitates industrial production. The radical polymerization may be solution polymerization, emulsion polymerization, bulk polymerization, or suspension polymerization. The radical polymerization is preferably solution polymerization. By using solution polymerization, the molecular weight of the copolymer can be easily controlled.

In the radical polymerization, before adding a polymerization initiator to polymerize the monomers, the monomers may be diluted with a polymerization solvent.

The polymerization solvent may be, for example, an ester solvent, alcohol ether solvent, ketone solvent, aromatic solvent, amide solvent, or alcohol solvent. The ester solvent may be, for example, methyl acetate, ethyl acetate, n-butyl acetate, isobutyl acetate, t-butyl acetate, methyl lactate, or ethyl lactate. The alcohol ether solvent may be, for example, ethylene glycol monomethyl ether, ethylene glycol monoethyl ether, propylene glycol monomethyl ether, propylene glycol monomethyl ether acetate, propylene glycol monoethyl ether, 3-methoxy-1-butanol, or 3-methoxy-3-methyl-1-butanol. The ketone solvent may be, for example, acetone, methyl ethyl ketone, methyl isobutyl ketone, or cyclohexanone. The aromatic solvent may be, for example, benzene, toluene, or xylene. The amide solvent may be, for example, formamide or dimethylformamide. The alcohol solvent may be, for example, methanol, ethanol, n-propanol, isopropanol, n-butanol, isobutanol, s-butanol, t-butanol, diacetone alcohol, or 2-methyl-2-butanol. One of the polymerization solvents described above may be used alone or two or more may be mixed together.

The radical polymerization initiator may be, for example, a peroxide or an azo compound. The peroxide may be, for example, benzoyl peroxide, t-butyl peroxyacetate, t-butyl peroxybenzoate, or di-t-butyl peroxide. The azo compound may be, for example, azobisisobutyronitrile, an azobisamidinopropane salt, an azobiscyanovaleric acid (salt), or 2,2′-azobis[2-methyl-N-(2-hydroxyethyl) propionamide].

When the total amount of monomers is set to 100 parts by mass, the amount of the radical polymerization initiator is preferably 0.0001 parts by mass or higher and 20 parts by mass or lower, more preferably 0.001 parts by mass or higher and 15 parts by mass or lower, and further preferably 0.005 parts by mass or higher and 10 parts by mass or lower. The radical polymerization initiator may be added to the monomers and the polymerization solvent before initiating polymerization or may be dropped into the polymerization reaction system. Dropping the radical polymerization initiator into the polymerization reaction system for the monomers and the polymerization solvent is preferable in that the heat generation caused by polymerization can be suppressed.

The reaction temperature for radical polymerization is selected as appropriate according to the kinds of radical polymerization initiator and polymerization solvent. The reaction temperature is preferably 60° C. or higher and 110° C. or lower in order to facilitate manufacturing and reaction control.

When the resin having a radical scavenging amine structure is a polymer with the structural unit represented by formula (ii), the content of the structural unit represented by formula (ii) is preferably 1 to 95 mol %, more preferably 10 to 90 mol % based on the total molar quantity of the monomers constituting the active energy radiation-curable resin (B). When the content of the structural unit represented by formula (ii) is within this range, the light resistance and heat resistance of the dye (A) are improved, which in turn assists fading suppression.

Examples of the monofunctional (meth)acrylate compound the active energy radiation-curable resin (B) may contain include 2-hydroxyethyl (meth)acrylate, 2-hydroxypropyl (meth)acrylate, 2-hydroxybutyl (meth)acrylate, n-butyl (meth)acrylate, isobutyl (meth)acrylate, t-butyl (meth)acrylate, glycidyl (meth)acrylate, acryloylmorpholine, N-vinylpyrrolidone, tetrahydrofurfuryl acrylate, cyclohexyl (meth)acrylate, 2-ethylhexyl (meth)acrylate, isobornyl (meth)acrylate, isodecyl (meth)acrylate, lauryl (meth)acrylate, tridecyl (meth)acrylate, cetyl (meth)acrylate, stearyl (meth)acrylate, benzyl (meth)acrylate, 2-ethoxyethyl (meth)acrylate, 3-methoxybutyl (meth)acrylate, ethyl carbitol (meth)acrylate, phosphate (meth)acrylate, ethylene-oxide-modified phosphate (meth)acrylate, phenoxy (meth)acrylate, ethylene-oxide-modified phenoxy (meth)acrylate, propylene-oxide-modified phenoxy (meth)acrylate, nonyl phenol (meth)acrylate, ethylene-oxide-modified nonyl phenol (meth)acrylate, propylene-oxide-modified nonyl phenol (meth)acrylate, methoxy diethylene glycol (meth)acrylate, methoxy polyethylene glycol (meth)acrylate, methoxy propylene glycol (meth)acrylate, 2-(meth)acryloyl oxyethyl-2-hydroxy propyl phthalate, 2-hydroxy-3-phenoxy propyl (meth)acrylate, 2-(meth)acryloyl oxyethyl hydrogen phthalate, 2-(meth)acryloyl oxypropyl hydrogen phthalate, 2-(meth)acryloyl oxypropyl hexahydro hydrogen phthalate, 2-(meth)acrylol oxypropyl tetrahydro hydrogen phthalate, dimethylaminocthyl (meth)acrylate, trifluorocthyl (meth)acrylate, tetrafluoropropyl (meth)acrylate, hexafluoropropyl (meth)acrylate, octafluoropropyl (meth)acrylate, and adamantine derivative mono (meth)acrylate, such as adamantyl acrylate having monovalent mono (meth)acrylate which is derived from 2-adamantane and adamantine diol. Here, “(meth)acryloyl” means both or one of “acryloyl” and “methacryloyl”.

Examples of the bifunctional (meth)acrylate compound the active energy radiation-curable resin (B) may contain include di(meth)acrylates, such as ethylene glycol di(meth)acrylate, diethylene glycol di(meth)acrylate, butanediol di(meth)acrylate, hexanediol di(meth)acrylate, nonanediol di(meth)acrylate, ethoxylated hexanediol di(meth)acrylate, propoxylated hexanediol di(meth)acrylate, diethylene glycol di(meth)acrylate, polyethylene glycol di(meth)acrylate, tripropylene glycol di(meth)acrylate, polypropylene glycol di(meth)acrylate, neopentyl glycol di(meth)acrylate, ethoxylated neopentyl glycol di(meth)acrylate, tripropylene glycol di(meth)acrylate, and hydroxy pivalate neopentyl glycol di(meth)acrylate.

Examples of the trifunctional (meth)acrylate compound or (meth)acrylate compound having more functional groups that the active energy radiation-curable resin (B) may contain include tri(meth)acrylates such as trimethylolpropane tri(meth)acrylate, ethoxylated trimethylolpropane tri(meth)acrylate, propoxylated trimethylolpropane tri(meth)acrylate, tris2-hydroxyethylisocyanurate tri(meth)acrylate or glycerin tri(meth)acrylate, trifunctional (meth)acrylate compounds such as pentacrythritol tri(meth)acrylate, dipentacrythritol tri(meth)acrylate or ditrimethylolpropane tri(meth)acrylate, polyfunctional (meth)acrylate compounds having three or more functional groups such as pentaerythritol tetra(meth)acrylate, ditrimethylolpropane tetra(meth)acrylate, dipentaerythritol tetra(meth)acrylate, dipentaerythritol penta(meth)acrylate, ditrimethylolpropane penta(meth)acrylate, dipentaerythritol hexa(meth)acrylate or ditrimethylolpropane hexa(meth)acrylate, and polyfunctional (meth)acrylate compounds obtained by substituting part of these (meth)acrylate substituted with an alkyl group or e-caprolactone.

Urethane (meth)acrylate can also be used as the resin that the active energy radiation-curable resin (B) may contain. Examples of urethane (meth)acrylate include those obtained by reacting a (meth)acrylate monomer having a hydroxyl group with a product of the reaction between a polyester polyol with an isocyanate monomer or a prepolymer.

Examples of urethane (meth)acrylate include a pentaerythritol triacrylate hexamethylene diisocyanate urethane prepolymer, dipentaerythritol pentaacrylate hexamethylene diisocyanate urethane prepolymer, pentaerythritol triacrylate toluene diisocyanate urethane prepolymer, dipentaerythritol pentaacrylate toluene diisocyanate urethane prepolymer, pentaerythritol triacrylate isophorone diisocyanate urethane prepolymer, and dipentaerythritol pentaacrylate isophorone diisocyanate urethane prepolymer.

The above-listed other monofunctional, bifunctional, or trifunctional (meth)acrylate monomers or urethane (meth)acrylates, those with more functional groups, or the like that the active energy radiation-curable resin (B) can contain may be used alone or in combination of two or more. It may also be a partially polymerized oligomer.

The content of the active energy radiation-curable resin (B) is preferably 20 to 80% by mass, more preferably 30 to 70% by mass based on the total mass of the composition for forming the colored layer. When the content of the active energy radiation-curable resin (B) is equal to or higher than the lower limit, the effect of suppressing fading can be further enhanced.

When the content of the active energy radiation-curable resin (B) is equal to or lower than the upper limit, the composition for forming the colored layer can be handled even more easily.

### Photoinitiator (C)

For example, when ultraviolet light is used as the active energy radiation, the photoinitiator (C) generates radicals when irradiated with ultraviolet light.

Examples of photoinitiators (C) include benzoins (including benzoin and benzoin alkyl ethers such as benzoin methyl ether, benzoin ethyl ether, and benzoin isopropyl ether), phenyl ketones [for example, acetophenones (including acetophenone, 2-hydroxy-2-methyl-1-phenylpropane-1-one, 2,2-dimethoxy-2-phenylacetophenone, 2,2-diethoxy-2-phenylacetophenone, and 1,1-dichloroacetophenone), alkylphenyl ketones such as 2-hydroxy-2-methylpropiophenone; and cycloalkylphenyl ketones such as 1-hydroxycyclohexylphenyl ketone], aminoacetophenones {including 2-methyl-1-[4-(methylthio)phenyl]-2-morpholinoaminopropanone-1,2-benzyl-2-dimethylamino-1-(4-morpholinophenyl)-butanone-1}, anthraquinones (including anthraquinone, 2-methylanthraquinone, 2-ethylanthraquinone, 2-t-butylanthraquinone, and 1-chloroanthraquinone), thioxanthones (including 2,4-dimethylthioxanthone, 2,4-diethylthioxanthone, 2-chlorothioxanthone, and 2,4-diisopropylthioxanthone), ketals (including acetophenone dimethyl ketal and benzyl dimethyl ketal), benzophenones (including benzophenone), xanthones, and phosphine oxides (for example, 2,4,6-trimethylbenzoyldiphenylphosphine oxide). These photoinitiators may be used singly or in combination of two or more.

The content of the photoinitiator (C) is preferably 0.01 to 20 mass %, more preferably 0.01 to 5 mass % based on the total mass of the solid content of the composition for forming the colored layer. When the content of the photoinitiator (C) is less than the lower limit, the curing effect will be insufficient. When the content of the photoinitiator (C) exceeds the upper limit, part of the photoinitiator (C) remains unreacted and degrades the reliability of properties such as heat resistance.

### Solvent (D)

Examples of the solvent (D) include ethers, ketones, esters, and cellosolves. Examples of ethers include dibutyl ether, dimethoxymethane, dimethoxyethane, diethoxyethane, propylene oxide, 1,4-dioxane, 1,3-dioxolane, 1,3,5-trioxane, tetrahydrofuran, anisole, and phenetol. Examples of ketones include acetone, methyl ethyl ketone, diethyl ketone, dipropyl ketone, diisobutyl ketone, methyl isobutyl ketone, cyclopentanone, cyclohexanone, methylcyclohexanone, and ethylcyclohexanone. Examples of esters include ethyl formate, propyl formate, n-pentyl formate, methyl acetate, ethyl acetate, methyl propionate, ethyl propionate, n-pentyl acetate, and γ-butyrolactone. Examples of cellosolves include methyl cellosolve, cellosolve (ethyl cellosolve), butyl cellosolve, and cellosolve acetate. One or a combination of two or more of the solvents (D) may be used.

The content of the solvent (D) is preferably 20 to 80 mass %, more preferably 30 to 70 mass % relative to the total mass of the composition for forming the colored layer. When the content of the solvent (D) is equal to or higher than the lower limit, the composition for forming the colored layer can be handled even easier. When the content of the solvent (D) is equal to or lower than the upper limit, the time required to form the colored layer can be reduced.

### Additive (E)

The additive (E) contains at least a compound having a structure represented by the following formula (i) (hereinafter referred to as “compound A”) and a sulfur antioxidant.

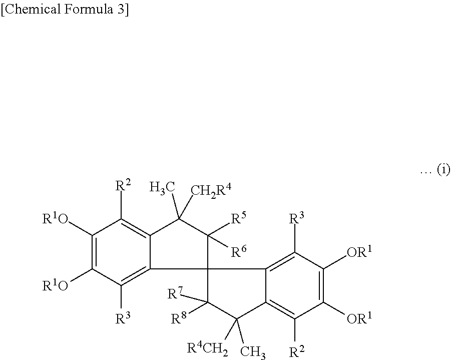

In formula (i), each R¹ independently represents any one of an alkyl group, an alkenyl group, an aryl group, a heterocyclic group, R⁹CO—, R¹⁰SO₂—, and R¹¹NHCO— (R⁹, R¹⁰, and R¹¹ are each independently any one of an alkyl group, an alkenyl group, an aryl group, and a heterocyclic group). R² and R³ each independently represent a hydrogen atom, a halogen atom, an alkyl group, an alkenyl group, an alkoxy group, or an alkenyloxy group. R⁴ to R⁸ each independently represent a hydrogen atom, an alkyl group, an alkenyl group, or an aryl group.

Examples of the sulfur antioxidant include dialkyldithiophosphate, dialkyldithiocarbanate, benzenedithiol, and transition metal complexes thereof.

The inventors found that by mixing the compound A and sulfur antioxidant in a predetermined ratio in the composition for forming the colored layer, the light resistance and heat resistance of the dye (A) can be significantly improved.

The predetermined ratio is in the range where the mass of compound A is 0.01 or more and 2 or less when the mass of the sulfur antioxidant is taken as 1. That is, the predetermined ratio is a ratio where the content of the compound A is 0.01 to 2 when the content of the sulfur antioxidant in the composition for forming the colored layer is taken as 1.

The additive (E) may include another additive such as a leveling agent, antifoaming agent, antioxidant, ultraviolet absorber, photostabilizer, photosensitizer, or conductive material.

The total mass of the compound (A) and the sulfur antioxidant in the additive (E) is preferably 0.1 to 15 mass %, more preferably 0.1 to 10 mass % based on the total mass of the solid content of the composition for forming the colored layer. When the content is less than the lower limit, the effect of suppressing fading is not obtained with regard to the light resistance and heat resistance of the dye (A). When the content of the additive (E) exceeds the upper limit, it tends to lead to insufficient curing due to curing inhibition by the additive (E) and/or a decreased amount of the curing component.

By containing the composition for forming a colored layer of the present invention, the colored layer 10 improves light resistance and heat resistance without requiring the gas barrier layer, which makes it possible to achieve both reflection suppression and luminance efficiency, improve display quality, extend the life of the light-emitting elements, and improve color reproducibility.

### Transparent Substrate

The transparent substrate 20 is a sheet-like member located on one surface of the colored layer 10 and forming an optical film 1.

A resin film having translucency may be used as the transparent substrate 20. The forming material of the transparent substrate 20 may be a transparent resin or inorganic glass. Examples of transparent resin include polyolefin, polyester, polyacrylate, polyamide, polyimide, polyarylate, polycarbonate, triacetyl cellulose, polyvinyl alcohol, polyvinyl chloride, cycloolefin copolymer, norbornene-containing resin, polyether sulfone, and polysulfone. Examples of polyolefins include polyethylene polypropylene. Examples of polyesters include polyethylene terephthalate, polybutylene terephthalate, and polyethylene naphthalate. An example of polyacrylate is polymethyl methacrylate. Examples of polyamides include nylon 6 and nylon 6,6. Among these, suitable examples are a film of polyethylene terephthalate (PET), a film of triacetyl cellulose (TAC), a film of polymethyl methacrylate (PMMA), and a film of polyester other than PET.

Although the thickness of the transparent substrate 20 is not specifically limited, it is preferably in a range of 10 to 100 μm, for example.

The transmittance of the transparent substrate 20 is preferably, for example, 90% or higher.

The transparent substrate 20 may be provided with the ability to absorb ultraviolet light. The transparent substrate 20 can be given the ability to absorb ultraviolet light by adding an ultraviolet absorber to the resin material of the transparent substrate 20.

Examples of ultraviolet absorbers include salicylic acid ester ultraviolet absorbers, benzophenone ultraviolet absorbers, benzotriazole ultraviolet absorbers, benzotriazine ultraviolet absorbers, and cyanoacrylate ultraviolet absorbers.

These ultraviolet absorbers may be used singly or in combination of two or more.

When the transparent substrate 20 is provided with the ability to absorb ultraviolet light, it preferably has an ultraviolet shielding rate of 85% or higher. The ultraviolet shielding rate is a value measured in accordance with JIS L 1925 and is calculated by the following formula.

Ultraviolet shielding rate (%)=100—Average transmittance of ultraviolet light with a wavelength of 290 to 400 nm (%)

An ultraviolet shielding rate below 85% reduces the effect of suppressing fading with regard to the light resistance of the dye (A).

### Functional Layer

The functional layer 30 is located on the one or the other surface of the colored layer 10. By having the functional layer 30, the optical film can exhibit various functions.

Examples of the functions of the functional layer 30 include antireflection function, antiglare function, antistatic function, stain-proof function, reinforcement function, and ultraviolet absorption function (ability to absorb ultraviolet).

The functional layer 30 may be a monolayer or a multilayer. The functional layer 30 may have one function or two or more functions.

When the optical film 1 has an antireflection function, the functional layer 30 functions as an antireflection layer. Examples of the antireflection layer include a hard coat layer 32, an antiglare layer 34, and a low refractive index layer 31 having a lower refractive index than the transparent substrate 20, which will be described later. The low refractive index layer 31 can be formed by using, for the functional layer, a material having a lower refractive index than the materials of the hard coat layer 32, the antiglare layer 34, and the transparent substrate 20.

To adjust the refractive index of the low refractive index layer 31, fine particles of lithium fluoride (LiF), magnesium fluoride (MgF₂), sodium hexafluoroaluminum (cryolite, 3NaF·AlF₃, Na₃AlF₆), or aluminum fluoride (AlF₃), or fine silica particles may be added. It is effective to use particles having voids inside them, such as fine, porous silica particles or hollow silica particles, as the fine silica particles to reduce the refractive index of the low refractive index layer 31. The photoinitiator (C), solvent (D), or additive (E) described in relation to the colored layer 10 may be added to the composition for forming the low refractive index layer 31 (composition for forming a low refractive index layer) as appropriate.

The refractive index of the low refractive index layer 31 is preferably 1.20 to 1.55.

Although the thickness of the low refractive index layer 31 is not specifically limited, it is preferably in a range of 40 nm to 1 μm, for example.

When the optical film 1 has an antiglare function, the functional layer 30 functions as an antiglare layer 34. The antiglare layer 34 has small irregularities on its surface so that they scatter external light to suppress reflection and in turn improve display quality. When combined with the low refractive index layer 31, the low refractive index layer 31 and the antiglare layer 34 constitute an antireflection layer.

The antiglare layer 34 contains at least one selected from fine organic particles and fine inorganic particles as necessary. The fine organic particles are materials that form the small irregularities on the surface and provide the function of scattering external light. Examples of fine organic particles include resin particles of translucent resin materials such as acrylic resin, polystyrene resin, styrene-(meth)acrylate copolymers, polyethylene resin, epoxy resin, silicone resin, polyvinylidene fluoride, and polyethylene fluoride resin. In order to adjust the refractive index and the dispersibility of resin particles, two or more kinds of resin particles having different characteristics (refractive indexes) may be mixed.

The fine inorganic particles are a material for controlling sedimentation and aggregation of the fine organic particles. Examples of fine inorganic particles include fine silica particles, fine metal oxide particles, and fine particles of various minerals. Examples of fine silica particles include colloidal silica, and fine silica particles surface-modified with a reactive functional group such as an (meth)acryloyl group. Examples of fine metal oxide particles include fine particles of alumina (aluminum oxide), zinc oxide, tin oxide, antimony oxide, indium oxide, titania (titanium dioxide), and zirconia (zirconium dioxide). Examples of fine mineral particles include fine particles of mica, synthetic mica, vermiculite, montmorillonite, iron-montmorillonite, bentonite, beidellite, saponite, hectorite, stevensite, nontronite, magadiite, ilerite, kanemite, layered titanate, smectite, and synthetic smectite. The fine mineral particles may either be natural or synthetic (including substituted products and derivatives), and also a mixture of both may be used. Among these fine mineral particles, organic layered clay is more preferable. Organic layered clay refers to a swellable clay in which organic onium ions are introduced between layers. The organic onium ion is not particularly limited as long as it can organicize the swellable clay by using the cation exchange property of the swellable clay. When an organic layered clay mineral is used as the fine mineral particles, synthetic smectite can be suitably used. Synthetic smectite has the function of increasing the viscosity of the coating liquid for forming the antiglare layer. This suppresses the sedimentation of resin particles and fine inorganic particles and adjusts the shape of the irregularities on the surface of the antiglare layer 34 (functional layer 30).

When the optical film 1 has an antistatic function, the functional layer 30 functions as an antistatic layer. Examples of the antistatic layer include layers containing antistatic agents such as fine metal oxide particles such as antimony-doped tin oxide (ATO) and tin-doped indium oxide (ITO), polymeric conductive compositions, and quaternary ammonium salts.

The antistatic layer may be provided on the outermost surface of the functional layer 30 or between the functional layer 30 and the transparent substrate 20. Alternatively, the antistatic layer may be formed by adding an antistatic agent to one of the above-described layers constituting the functional layer 30. When an antistatic layer is provided, the optical film preferably has a surface resistance of 1.0×10⁶ to 1.0×10¹² (Ω/cm).

When the optical film 1 has an antifouling function, the functional layer 30 functions as an antifouling layer. The stain-proof layer improves the antifouling performance by imparting both or one of water repellency and oil repellency. Examples of the antifouling layer include layers containing antifouling agents such as silicon oxide, fluorine-containing silane compounds, fluoroalkylsilazane, fluoroalkylsilane, fluorine-containing silicon compounds, and perfluoropolyether group-containing silane coupling agents.

The antifouling layer may be provided on the outermost surface of the functional layer 30, or formed by adding an antifouling agent to the outermost layer of the functional layer(s) 30.

When the optical film 1 has a reinforcement function, the functional layer 30 functions as a reinforcement layer. The reinforcement layer is a layer that reinforces the optical film. An example of the reinforcement layer is the hard coat layer 32. Examples of the hard coat layer 32 include layers formed with a hard coat agent containing monofunctional, bifunctional, or trifunctional (meth)acrylate or urethane (meth)acrylate, or (meth)acrylate or urethane (meth)acrylate with more functional groups.

When the optical film 1 has the ability to absorb ultraviolet light, the functional layer 30 functions as an ultraviolet absorbing layer. Examples of the ultraviolet absorbing layer include layers containing triazine ultraviolet absorbers such as 2-(4,6-diphenyl-1,3,5-triazin-2-yl)-5-hexyloxyphenol and benzotriazole ultraviolet absorbers such as 2-(2H-benzotriazole-2-yl)-4-methylphenol.

The content of the ultraviolet absorber is preferably 0.1 to 5 mass % based on the total mass of the materials forming the ultraviolet absorbing layer. When the content of the ultraviolet absorber is equal to or higher than the lower limit, the functional layer 30 can be provided with sufficient ultraviolet absorbance. When the content of the ultraviolet absorber is equal to or lower than the upper limit, it is possible to avoid insufficient hardness due to a decrease in the amount of the curing component.

In the optical film 1, one or both of the transparent substrate 20 and the functional layer 30 have an ultraviolet shielding rate of 85% or higher, preferably 90% or higher, more preferably 95% or higher. It may even be 100%. When the ultraviolet shielding rate is equal to or higher than the lower limit, light resistance and heat resistance can be further improved.

The ultraviolet shielding rate can be measured according to the method described in JIS L 1925.

The ultraviolet shielding rate can be adjusted by imparting ultraviolet absorbing ability to one or both of the transparent substrate 20 and the functional layer 30.

The thickness of the functional layer 30 is, for example, preferably in a range of 0.04 to 25 μm, more preferably 0.1 to 20 μm, and still more preferably 0.2 to 15 μm. When the thickness of the functional layer 30 is equal to or greater than the lower limit, it becomes easier to impart various functions to the optical film 1. When the thickness of the functional layer 30 is equal to or smaller than the upper limit, it is advantageous in making the display device thinner.

### Method of Manufacturing Optical Film

The optical film 1 of this embodiment can be manufactured by a conventionally known method.

For example, the colored layer 10 may be obtained by applying a composition for forming the colored layer to one surface of the transparent substrate 20 and curing the composition by irradiating it with active energy radiation.

The light source for irradiating the composition for forming the colored layer with active energy radiation to cure it and form the colored layer 10 can be any light source that generates active energy radiation. Examples of the active energy radiation include optical energy radiation such as radiation (such as gamma rays and X-rays), ultraviolet light, visible light, and electron beams (EB). Usually ultraviolet light and electron beams are used. Examples of lamps emitting ultraviolet light include low-pressure mercury vapor lamps, medium-pressure mercury vapor lamps, high-pressure mercury vapor lamps, carbon arc lamps, metal halide lamps, xenon lamps, and electrodeless lamps. As irradiation conditions, the integrated UV irradiation amount is usually 100-1000 mJ/cm².

Next, a hard coat agent is applied to the other surface of the transparent substrate 20. As with the colored layer 10, the applied hard coat agent is irradiated with active energy radiation to cure it, thereby obtaining the hard coat layer 32.

By forming the low refractive index layer 31 on the hard coat layer 32, an optical film 1 having the functional layer 30 on the other surface of the transparent substrate 20 can be obtained.

The method of forming the low refractive index layer 31 is not particularly limited. For example, it may be formed by applying a composition for forming a low refractive index layer to the hard coat layer 32 and irradiating the applied composition with active energy radiation to cure it, vacuum evaporation, sputtering, ion plating, an ion beam method, or plasma-enhanced chemical vapor deposition.

### Other Embodiments

As shown in FIG. 2, the optical film may be an optical film 3 in which the transparent substrate 20 is located on one surface of the colored layer 10, and the colored layer 10, the transparent substrate 20, and the antiglare layer 34 are laminated in this order. In the optical film 3, the antiglare layer 34 forms the functional layer 30.

Since the optical film 3 of this embodiment has the antiglare layer 34, it suppresses reflection well.

As shown in FIG. 3, the optical film may be an optical film 4 in which the transparent substrate 20 is located on one surface of the colored layer 10, and the colored layer 10, the transparent substrate 20, the antiglare layer 34, and the low refractive index layer 31 are laminated in this order. In the optical film 4, the antiglare layer 34 and the low refractive index layer 31 constitute the functional layer 30.

Since the optical film 4 of this embodiment has the low refractive index layer 31 and the antiglare layer 34, it suppresses reflection even better.

As shown in FIG. 4, the optical film may be an optical film 5 in which the transparent substrate 20 is located on one surface of the colored layer 10, and the functional layer 30 is located on the other surface of the colored layer 10. In the optical film 5, the transparent substrate 20, the colored layer 10, the hard coat layer 32, and the low refractive index layer 31 are laminated in this order. In the optical film 5, the hard coat layer 32 and the low refractive index layer 31 constitute the functional layer 30.

The optical film 5 of this embodiment has the colored layer 10 and the functional layer 30 having an ultraviolet absorbing function and an antireflection function on one surface of the transparent substrate 20. The ultraviolet absorbing function may be imparted to any of the layers forming the functional layer.

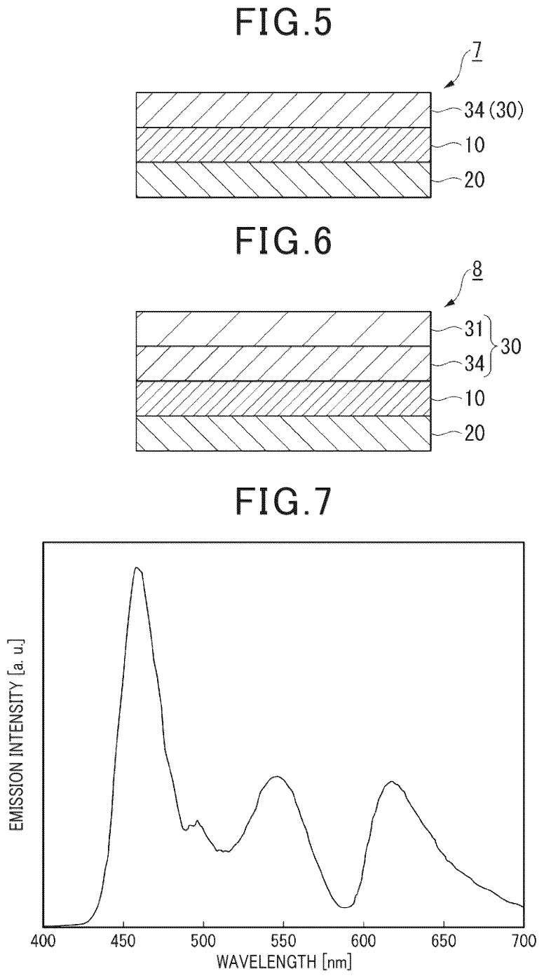

As shown in FIG. 5, the optical film may be an optical film 7 in which the transparent substrate 20 is located on one surface of the colored layer 10, and the antiglare layer 34 is located on the other surface of the colored layer 10. In the optical film 7, the transparent substrate 20, the colored layer 10, and the antiglare layer 34 are laminated in this order. In the optical film 7, the antiglare layer 34 forms the functional layer 30.

Since the optical film 7 of this embodiment has the antiglare layer 34, it suppresses reflection well.

In the optical film 7, it is preferable to impart an ultraviolet absorbing function to the antiglare layer 34.

As shown in FIG. 6, the optical film may be an optical film 8 in which the transparent substrate 20 is located on one surface of the colored layer 10, and the functional layer 30 is located on the other surface of the colored layer 10. In the optical film 8, the transparent substrate 20, the colored layer 10, the antiglare layer 34, and the low refractive index layer 31 are laminated in this order. In the optical film 8, the antiglare layer 34 and the low refractive index layer 31 constitute the functional layer 30.

Since the optical film 8 of this embodiment has the low refractive index layer 31 and the antiglare layer 34, it suppresses reflection even better.

In the optical film 8, it is preferable to impart an ultraviolet absorbing function to one of the layers forming the functional layer 30.

### Display Device

The display device of the present invention has the optical film of the present invention. Specific examples of electronic devices include television, monitors, mobile phones, portable game machines, portable information terminals, personal computers, electronic books, video cameras, digital still cameras, head mounted displays, navigation systems, sound reproduction devices (car audio systems, digital audio players, and the like), copiers, facsimiles, printers, multifunction printers, vending machines, automated teller machines (ATM), personal identification devices, optical communication devices, and IC cards. It can be particularly suitably applied to display devices having self-emissive elements such as LEDs, organic EL, inorganic phosphors, and quantum dots that are susceptible to external light reflection due to metal electrodes and wiring

According to the optical film of each of the above described embodiments, since it has a colored layer containing the composition for forming a colored layer of the present invention, it is possible to improve light resistance and heat resistance without providing a gas barrier layer, and achieve both reflection suppression and luminance efficiency. This allows a display device including the optical film of this embodiment to improve display quality and extend the life of the light-emitting elements.

Embodiments of the present invention have so far been described in detail with reference to the drawings. However, specific configurations are not limited to this embodiment. The present invention should encompass modifications, combinations, or the like of this embodiment, in the range not departing from the spirit of the present invention.

For example, although the optical films described above have one colored layer, there may be two or more colored layers.

In the optical film according to each embodiment, the ultraviolet absorbing ability may be imparted to the transparent substrate 20 or to the functional layer 30 such as the hard coat layer 32. What is important is that the ultraviolet absorbing ability is imparted to a layer that is closer to the screen viewed by the user than the colored layer 10 is when the optical film is attached to the display device.

### EXAMPLES

Now, the present invention will be described more closely using Examples. The technical scope of the present invention should not be limited in any way solely based on the specific contents of these Examples.

### Examples 1 to 8 and Comparative Examples 1 to 6

In the following Examples and Comparative Examples, optical films A to N having the layer structures shown in Tables 1 and 2 were prepared. Simulations were performed using the prepared optical films A to N to evaluate their optical film characteristics, and display device characteristics when applied to an organic EL panel. In the tables, “-” means that the layer is not present.

TABLE 1

| | Ex. 1 | Ex. 2 | Ex. 3 | Ex. 4 | Ex. 5 | Ex. 6 | Ex. 7 | Ex. 8 |
|---|---|---|---|---|---|---|---|---|
| Optical film | Optical | Optical | Optical | Optical | Optical | Optical | Optical | Optical |
| | film A | film B | film C | film D | film E | film F | film G | film H |
| Functional | Low | Low | Low | Low | Low | — | Low | Low |
| layer 1 | refractive | refractive | refractive | refractive | refractive | | refractive | refractive |
| | index | index | index | index | index | | index | index |
| | layer | layer | layer | layer | layer | | layer | layer |
| Functional | Hard coat | Hard coat | Hard coat | Hard coat | Hard coat | Antiglare | Antiglare | Hard coat |
| layer 2 | layer 1 | layer 1 | layer 1 | layer 1 | layer 1 | layer | layer | layer 2 |
| Colored | — | — | — | — | — | — | — | Colored |
| layer | | | | | | | | layer d |
| Substrate | TAC | TAC | TAC | TAC | TAC | TAC | TAC | PMMA |
| Colored | Colored | Colored | Colored | Colored | Colored | Colored | Colored | — |
| layer | layer a | layer b | layer c | layer d | layer e | layer d | layer d | |

TABLE 2

| | Comp. | Comp. | Comp. | Comp. | Comp. | Comp. |
|---|---|---|---|---|---|---|
| | Ex. 1 | Ex. 2 | Ex. 3 | Ex. 4 | Ex.5 | Ex. 6 |
| Optical film | Optical | Optical | Optical | Optical | Optical | Optical |
| | film I | film J | film K | film L | film M | film N |
| Functional | Low | Low | Low | Low | Low | Low |
| layer 1 | refractive | refractive | refractive | refractive | refractive | refractive |
| | index layer | index layer | index layer | index layer | index layer | index layer |
| Functional | Hard coat | Hard coat | Hard coat | Hard coat | Hard coat | Hard coat |
| layer 2 | layer 1 | layer 1 | layer 1 | layer 1 | layer 1 | layer 1 |
| Colored | — | — | — | — | Colored | — |
| layer | | | | | layer j | |
| Substrate | TAC | TAC | TAC | TAC | TAC | TAC |
| Colored | Colored | Colored | Colored | Colored | — | — |
| layer | layer f | layer g | layer i | layer h | | |

### <<Preparation of Optical Film>>

How the layers were formed will be described.

### Formation of Colored Layer

### (Materials of Composition for Forming Colored Layer)

The following materials were used for the composition for forming the colored layer.

Note that the wavelength of maximum absorption, the full width at half maximum, and the wavelength of minimum transmittance in a specified wavelength range of a coloring material are its characteristic values in the state of a cured coating film.

### <Dye (A)>

### First Coloring Material

Dye-1: Pyrromethene cobalt complex dye (with a wavelength of maximum absorption of 493 nm and a full width at half maximum of 26 nm)

### <Manufacturing Example of Dye-1>

After placing ethyl 5-formyl-2,4-dimethyl-1H-pyrrole-3-carboxylate (2.5 g) in a reaction vessel to dissolve it in methanol (50 mL), 47% hydrobromic acid (45 g) was added. The mixture was refluxed for 1 hour. By filtering the precipitated solid, 3,3′,5,5′-tetramethyl-4,4′-di-ethoxycarbonyl-2,2′-dipyrromethene hydrobromide (2.6 g) was obtained.

After placing 3,3′,5,5′-tetramethyl-4,4′-di-ethoxycarbonyl-2,2′-dipyrromethene hydrobromide (0.6 g) in a reaction vessel, methanol (5 mL), triethylamine (0.17 g), and cobalt acetate tetrahydrate (0.18 g) were added, and the mixture was refluxed for 2 hours. Dye-1 (0.42 g) was obtained by filtering the precipitated solid.

### Second Coloring Material

Dye-2: Tetraazaporphyrin copper complex dye (FDG-007 manufactured by Yamada Chemical Co., Ltd., with a wavelength of maximum absorption of 595 nm and a full width at half maximum of 22 nm)

Dye-3: Tetraazaporphyrin copper complex dye (PD-311S manufactured by Yamamoto Chemicals Inc., with a wavelength of maximum absorption of 586 nm and a full width at half maximum of 22 nm)

### Third Coloring Material

Dye-4: Phthalocyanine copper complex dye (FDN-002 manufactured by Yamada Chemical Co., Ltd., with a wavelength of minimum transmittance of 780 nm within 400 to 780 nm)

### Active Energy Radiation-Curable Resin (B)

1 Resin 1: A polymer containing a structural unit represented by the above formula (ii)
UA-306H: Pentaerythritol triacrylate hexamethylene diisocyanate urethane prepolymer (UA-306H manufactured by Kyoeisha Chemical Co., Ltd.)
DPHA: Dipentaerythritol hexaacrylate
PETA: Pentaerythritol triacrylate

### Manufacturing Example of Resin 1

2.4 g of 1,2,2,6,6-pentamethyl-4-piperidyl methacrylate (FA-711 MM manufactured by Resonac Corporation (formerly known as Showa Denko Materials Co., Ltd.)), 5.6 g of methyl methacrylate (manufactured by Kanto Chemical Co., Inc.), 31 g of cyclohexanone (manufactured by Kanto Chemical Co., Inc.), and 0.11 g of 2,2′-azobis(isobutyronitrile) (manufactured by FUJIFILM Wako Pure Chemical Corporation) were placed in a reaction vessel and heated and stirred for 8 hours at 70° C. in a nitrogen gas atmosphere. After that, the mixture was heated and stirred for 1 hour at 100° C. to obtain a polymer solution. This polymer solution was poured into 400 mL of methanol (manufactured by Kanto Chemical Co., Inc.) and then filtered to collect the precipitate. By drying the precipitate, the resin 1 that is a copolymer of 1,2,2,6,6-pentamethyl-4-piperidyl methacrylate: methyl methacrylate=15:85 [mol %] was obtained.

By additionally heating and stirring for an hour at 100° C., the initiator 2,2′-azobis(isobutyronitrile) can be completely decomposed. This suppresses deterioration of the optical film due to the remaining initiator.

By pouring the polymer solution into methanol, unreacted monomers, polymerization solvent, the products of the decomposition of the initiator, and the like can be removed, which suppresses deterioration of the optical film.

### Photoinitiator (C)

Omnirad TPO: An acyl phosphine oxide photoinitiator (manufactured by IGM Resins B.V.)

### Solvent (D)

MEK: Methyl ethyl ketone
Methyl acetate

### Additive (E)

Compound A: T1477
R¹:C₃H₇, R² to R⁸: H
Sulfur antioxidant: Bis(dibutyldithiocarbamic acid) nickel (II), D1781 manufactured by Tokyo Chemical Industry Co., Ltd.
Tinuvin 479: A hydroxyphenyltriazine ultraviolet absorber, Tinuvin (registered trademark) 479 (manufactured by BASF Japan Ltd.)
LA-36: A benzotriazole ultraviolet absorber, ADK STAB (registered trademark) LA-36 (manufactured by ADEKA CORPORATION)

### (Transparent Substrate)

The following films were used for the transparent substrates.
TAC: A triacetyl cellulose film (TG60UL manufactured by FUJIFILM Corporation, substrate thickness 60 μm, ultraviolet shielding rate 92.9%)
PMMA: A polymethyl methacrylate film (manufactured by Sumitomo Chemical Co., Ltd., W002N80, substrate thickness 80 μm, ultraviolet shielding rate 13.9%)

### (Formation of Colored Layer)

The compositions for forming colored layers shown in Table 3 were applied onto the transparent substrates shown in Tables 1 and 2, and dried in an oven at 80° C. for 60 seconds. After that, the coating film was cured by irradiating it with ultraviolet light at an irradiation dose of 150 mJ/cm² using an ultraviolet irradiation device (a light source, H-bulb, manufactured by Fusion UV Systems Japan (currently available from Heraeus Noblelight Japan)) so that a colored layer having a film thickness of 5.0 μm after curing is formed. Note that the amount added is expressed in mass ratio (mass %). In the tables, “-” signifies that the component is not present.

TABLE 3

| | | Colored | Colored | Colored | Colored | Colored | Colored | Colored | Colored | Colored | Colored |
|---|---|---|---|---|---|---|---|---|---|---|---|
| | | layer a | layer b | layer c | layer d | layer e | layer f | layer g | layer h | layer i | layer j |
| (A) Dye | 1st coloring | — | Dye-1 | | | | | | | | |
| | material | | | | | | | | | | |
| | Amount | — | 0.2% | 0.2% | 0.2% | 0.2% | 0.2% | 0.2% | 0.2% | 0.2% | 0.2% |
| | added | | | | | | | | | | |
| | 2nd coloring | Dye-2 | Dye-2/Dye-3 | | | | | | | | |
| | material | | | | | | | | | | |
| | Ratio | 100 | 40/60 | | | | | | | | |
| | Amount | 0.8% | 0.5% | 0.4% | 0.5% | 0.5% | 0.5% | 0.5% | 0.5% | 0.5% | 0.5% |
| | added | | | | | | | | | | |
| | 3rd coloring | — | — | Dye-4 | — | | — | — | — | — | — |
| | material | | | | | | | | | | |
| | Amount | — | — | 1.30% | — | | — | — | — | — | — |
| | added | | | | | | | | | | |
| (B) | Kind | UA-306H/ | | | Resin 1/UA- | | UA- | Resin 1/UA- | | | UA- |
| Active energy | | DPHA/PETA | | | 306H/DPHA/ | | 306H/DPHA/ | 306H/DPHA/ | | | 306H/DPHA/ |
| radiation- | | | | | PETA | | PETA | PETA | | | PETA |
| curable | Ratio | 70/20/10 | | | 30/49/14/7 | | 70/20/10 | 30/49/14/7 | | | 70/20/10 |
| resin | Amount | 42.9% | 43.0% | 41.8% | 43.0% | | 44.7% | 43.0% | 43.0% | 43.0% | 39.7% |
| | added | | | | | | | | | | |
| (C) | Kind | Omnirad TPO | | | | | | | | | |
| Photoinitiator | Amount | 4.6% | | | | | | | | | |
| | added | | | | | | | | | | |
| (D) Solvent | Kind | MEK/Methyl acetate | | | | | | | | | |
| | Ratio | 50/50 | | | | | | | | | |
| | Amount | 50% | | | | | | | | | |
| | added | | | | | | | | | | |
| (E) Additive | Kind | T1477/D1781 | | | | | — | T1477 | D1781 | T1477/ | T1477/D1781/ |
| | | | | | | | | | | D1781 | Tinuvin479/ |
| | | | | | | | | | | | LA-37 |
| | Ratio | 28/72 | | | | 66/34 | — | 100 | 100 | 75/25 | 28/72/38/25 |
| | Amount | 1.8% | 1.8% | 1.8% | 1.8% | 1.8% | — | 1.8% | 1.8% | 1.8% | 5.0% |
| | added | | | | | | | | | | |

### [Formation of Functional Layer: Hard Coat Layer]

### (Materials of Composition for Forming Hard Coat Layer)

The following materials were used for the composition for forming the hard coat layer.
Active energy radiation-curable resin
UA-306H: Pentaerythritol triacrylate hexamethylene diisocyanate urethane prepolymer (UA-306H manufactured by Kyoeisha Chemical Co., Ltd.)
DPHA: Dipentaerythritol hexaacrylate
PETA: Pentaerythritol triacrylate
Photoinitiator
Omnirad TPO: An acyl phosphine oxide photoinitiator (manufactured by IGM Resins B.V.)
Additive (ultraviolet (UV) absorber)
Tinuvin 479: A hydroxyphenyltriazine ultraviolet absorber, Tinuvin (registered trademark) 479 (manufactured by BASF Japan Ltd.)
LA-36: A benzotriazole ultraviolet absorber, ADK STAB (registered trademark) LA-36 (manufactured by ADEKA CORPORATION)
Solvent
MEK: Methyl ethyl ketone
Methyl acetate

### (Formation of Hard Coat Layer)

The compositions for forming hard coat layers shown in Table 4 were applied onto the transparent substrates or colored layers shown in Tables 1 and 2, and dried in an oven at 80° C. for 60 seconds. After that, the coating film was cured by irradiating it with ultraviolet light at an irradiation dose of 150 mJ/cm² using an ultraviolet irradiation device (a light source, H-bulb, manufactured by Fusion UV Systems Japan (currently available from Heraeus Noblelight Japan)) so that a hard coat layer having a film thickness of 5.0 μm after curing is formed. Note that the amount added is expressed in mass ratio (mass %). In the tables, “-” signifies that the component is not present.

TABLE 4

| | | Hard coat layer 1 | Hard coat layer 2 |
|---|---|---|---|
| Active | Kind | UA-306H/DPHA/PETA | |
| energy | Ratio | 70/20/10 | |
| radiation- | Amount added | 45.4% | 42.2% |
| curable resin | | | |
| Photoinitiator | Kind | Omnirad TPO | |
| | Amount added | 4.6% | |
| UV absorber | Kind | — | Tinuvin479/LA-36 |
| | Ratio | — | 40/60 |
| | Amount added | — | 3.2% |

| | | |
|---|---|---|
| Solvent | Kind | MEK/Methyl acetate |
| | Ratio | 50/50 |
| | Amount added | 50% |

### [Formation of Functional Layer: Antiglare Layer]

### (Composition for Forming Antiglare Layer)

The following materials were used for the composition for forming the antiglare

layer.
Active energy radiation-curable resin
A pentaerythritol triacrylate, Light Acrylate PE-3A (manufactured by Kyoeisha Chemical Co., Ltd., refractive index 1.52) 43.7 parts by mass
Photoinitiator
Omnirad TPO (manufactured by IGM Resins B.V.) 4.55 parts by mass—Resin particles
Styrene-methyl methacrylate copolymer particles (refractive index 1.515, average particle size 2.0 μm) 0.5 part by mass
Fine inorganic particles
Synthetic smectite 0.25 parts by mass
Alumina nanoparticles (average particle size 40 nm) 1.0 parts by mass
Solvent
Toluene 15 parts by mass
Isopropyl alcohol 35 parts by mass

### (Formation of Antiglare Layer)

The above composition for forming an antiglare layer was applied onto a transparent substrate shown in Table 1, and dried in an oven at 80° C. for 60 seconds. After that, the coating film was cured by irradiating it with ultraviolet light at an irradiation dose of 150 mJ/cm² using an ultraviolet irradiation device (a light source, H-bulb, manufactured by Fusion UV Systems Japan (currently available from Heraeus Noblelight Japan)) so that an antiglare layer having a film thickness of 5.0 μm after curing is formed.

### (Formation of Functional Layer: low Refractive Index Layer)

### (Composition for Forming the low Refractive Index Layer)

The following materials were used for the composition for forming the low refractive index layer.
Refractive index modifier
A dispersion of fine, porous silica particles (average particle size 75 nm, solid content 20%) in methyl isobutyl ketone 8.5 parts by mass
Stain-proof agent
Optool (registered trademark) AR-110 (manufactured by Daikin Industries, Ltd., solid content 15%, solvent: methyl isobutyl ketone) 5.6 parts by mass
Active energy radiation-curable resin
Pentaerythritol triacrylate (PETA) 0.4 parts by mass
Photoinitiator
Omnirad TPO (manufactured by IGM Resins B.V.) 0.07 parts by mass
Leveling agent
RS-77 (manufactured by DIC Corporation) 1.7 parts by mass
Solvent
Methyl ethyl ketone 83.73 parts by mass

### (Formation of low Refractive Index Layer)

The above composition for forming the low refractive index layer was applied onto the hard coat layers or oxygen barrier layers shown in Tables 1 and 2, and dried in an oven at 80° C. for 60 seconds. After that, the coating film was cured by irradiating it with ultraviolet light at an irradiation dose of 200 mJ/cm² using an ultraviolet irradiation device (a light source, H-bulb, manufactured by Fusion UV Systems Japan (currently available from Heraeus Noblelight Japan)) so that a low refractive index layer having a film thickness of 100 nm after curing is formed.

### [Evaluation of Film Characteristics]

### <Ultraviolet Shielding Rate on Colored Layer>

When the transparent substrate was used as a layer above the colored layer, the transmittance was measured using an automatic spectrophotometer (U-4100 manufactured by Hitachi, Ltd.). When the colored layer was provided above the substrate, the layers above the colored layer were peeled off using a transparent pressure-sensitive adhesive tape that satisfies the JIS-K 5600 May 6:1999 adhesion test. Then, using an adhesive tape as a reference, the transmittance of the layers above the colored layer was measured with an automatic spectrophotometer (U-4100 manufactured by Hitachi, Ltd.). These transmittance values were used to calculate the average transmittance [%] in the ultraviolet region (290 nm to 400 nm), and the ultraviolet shielding rate [%] was obtained by subtracting the average transmittance [%] in the ultraviolet region (290 nm to 400 nm) from 100%.

### <Light Resistance Test>

In the light resistance test of the obtained optical films, the films were tested using a xenon weather meter testing machine (X75 manufactured by Suga Test Instruments Co., Ltd.) for 120 hours with a xenon lamp illuminance of 60 W/m² (300 nm to 400 nm) and at a temperature of 45° C. and humidity (RH) of 50% inside the testing machine. Using an automatic spectrophotometer (U-4100 manufactured by Hitachi, Ltd.), the transmittance was measured before and after the test to calculate a transmittance difference ΔTλ1 before and after the test at a wavelength λ1 at which the minimum transmittance is obtained before the test within the wavelength range of 470 nm to 530 nm, as well as a transmittance difference ΔTλ2 before and after the test at a wavelength λ2 at which the minimum transmittance is obtained before the test within the wavelength range of 560 nm to 620 nm. The closer the transmittance difference is to zero, the better, and preferably |ΔTλN|≤20 (N=1 to 3), more preferably |ΔTλN|≤10 (N=1 to 3).

### <Heat Resistance Test>

In the heat resistance test of the obtained optical films, the films were tested for 500 hours at a temperature of 90° C. Using an automatic spectrophotometer (U-4100 manufactured by Hitachi, Ltd.), the transmittance was measured before and after the test to calculate a transmittance difference ΔTλ1 before and after the test at a wavelength λ1 at which the minimum transmittance is obtained before the test within the wavelength range of 470 nm to 530 nm, as well as a transmittance difference ΔTλ2 before and after the test at a wavelength λ2 at which the minimum transmittance is obtained before the test within the wavelength range of 560 nm to 620 nm. The closer the transmittance difference is to zero, the better, and preferably |ΔTλN|≤20 (N=1 to 3), more preferably |ΔTλN|≤10 (N=1 to 3).

### [Evaluation of Display Device Characteristics]

### <White Mode Transmission Property>

The transmittance of the obtained optical films was measured with an automatic spectrophotometer (U-4100 manufactured by Hitachi, Ltd.). Using this transmittance, the efficiency of light transmitted through the optical film during the white mode was calculated and used as an evaluation of the white mode transmission property. As a reference, the efficiency of the spectrum during the white mode output through a white organic EL light source and a color filter having the spectrum shown in FIG. 7 was set as 100. The closer it is to 100, the higher the white mode transmittance and the better the luminance efficiency.

### <Display Device Reflection Property>

The transmittance T(λ) and surface reflectance R2(λ) were measured for each of the obtained optical films using an automatic spectrophotometer (U-4100 manufactured by Hitachi, Ltd.). To measure the surface reflectance R2(λ), a matte black dye was applied to the surface of the transparent substrate on which the colored layer and functional layer are not formed to prevent reflection, and the spectral reflectance was measured at an incident angle of 5° and used as the surface reflectance R2(λ). Assuming that the electrode reflectance R_{E}(λ) is 100% throughout the wavelength range of 380 nm to 780 nm, without considering any interface reflection or surface reflection at each layer, and setting the reflectance of the display device without the optical film for D65 illuminant (Commission Internationale de l'Eclairage (CIE) standard illuminant D65) as 100, the relative reflection was calculated based on the following formulas (1) to (4). The surface reflectance R(λ) of the outermost layer on the observer's side was used as an evaluation of the display device reflection property. The lower the value of the display device reflection property, the more the reflection of external light can be reduced and the better the reflection property. Note that, in formulas (1) to (4), R1(λ) represents an internal reflection component, Y represents one of the tristimulus values at the white point of the light source D65, P_{D65}(λ) represents the spectrum of D65 illuminant, and y(λ) represents a CIE 1931 color matching function.

$$\begin{matrix}[ Equation 1 ] & \\ R 1 ( λ ) [ \% ] = \frac{( 100 - R 2 ( λ ) )}{100} \times \frac{T ( λ )}{100} \times \frac{T ( λ )}{100} \times {R}_{E} ( λ ) & ( 1 )\end{matrix}$$

$$\begin{matrix}[ Equation 2 ] & \\ R ( λ ) [ \% ] = R 1 ( λ ) + R 2 ( λ ) & ( 2 )\end{matrix}$$

$$\begin{matrix}[ Equation 3 ] & \\ \begin{matrix}Y = k \times {\int }_{380}^{780} {P}_{D 65} ( λ ) \times R ( λ ) \times \overline{y} ( λ ) & d λ\end{matrix} & ( 3 )\end{matrix}$$

$$\begin{matrix}[ Equation 4 ] & \\ k = 100 / {\int }_{380}^{780} {P}_{D 65} ( λ ) \times \overline{y} ( λ ) d λ & ( 4 )\end{matrix}$$

### <Color Reproducibility>

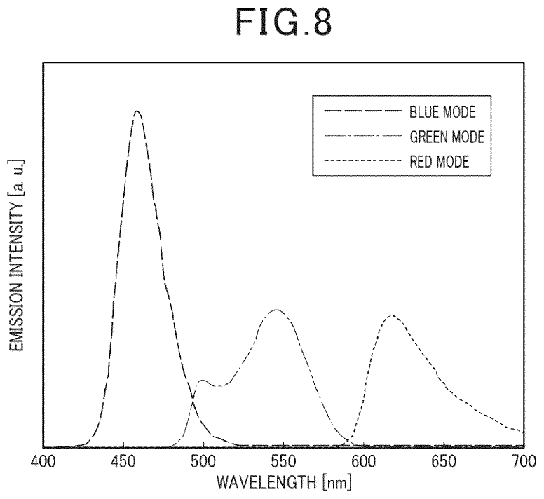

The transmittance of the obtained optical films was measured using an automatic spectrophotometer (U-4100 manufactured by Hitachi, Ltd.), and the red mode, green mode, and blue mode spectra of FIG. 8 output through the white EL light source and color filter having the spectrum shown in FIG. 7 was measured. The vertical axis of the graphs in FIGS. 7 and 8 indicates emission intensity [arbitrary unit (a. u.)]. The National Television Broadcast Standards Committee (NTSC) ratio was calculated from the CIE 1931 chromaticity value calculated using the measured transmittance and the red mode, green mode, and blue mode spectra in FIG. 8. The NTSC ratio was evaluated as a metric of the color reproducibility. The higher the NTSC ratio, the better the color reproducibility.

As evaluations of the characteristics of the optical films, the ultraviolet shielding rates on the colored layer, and the results of the light resistance test and the heat resistance test are shown in Tables 5 and 6. As evaluations of the characteristics of the display devices, the results of the white mode transmission property, display device reflection property, and color reproducibility are shown in Tables 5 and 6. Regarding Comparative Example 6 having an optical film M that does not include a colored layer, since the measurement of the ultraviolet shielding rate on the colored layer, the light resistance test, and the heat resistance test were not performed, “-” is given in the corresponding cells in Table 6. In addition, the ratio of the white mode transmission property based on the white mode transmission property in Comparative Example 6(ratio to Comparative Example 6), and the ratio of the display device reflection property based on the display device reflection property in Comparative Example 6 (ratio to Comparative Example 6) are shown in Tables 5 and 6, respectively.

TABLE 5

| | | Ex. 1 | Ex. 2 | Ex. 3 | Ex. 4 | Ex. 5 | Ex. 6 | Ex. 7 | Ex. 8 |
|---|---|---|---|---|---|---|---|---|---|
| UV shielding rate on | | 92.9% | 92.9% | 92.9% | 92.9% | 92.9% | 92.9% | 92.9% | 90.5% |
| colored layer | | | | | | | | | |
| Lightfastness | ΔTλ1 | — | 9.8 | 9.6 | 4.8 | 5.2 | 4.9 | 4.8 | 5.7 |
| | ΔTλ2 | 1.3 | 1.3 | 1.0 | 1.3 | 1.4 | 1.2 | 1.3 | 1.3 |
| Heat resistance | ΔTλ1 | — | 12.3 | 12.2 | 8.0 | 8.5 | 8.1 | 8.2 | 8.7 |
| | ΔTλ2 | 1.1 | 1.3 | 1.3 | 0.6 | 0.6 | 0.9 | 0.8 | 1.0 |
| White mode transmission | | 61.0 | 61.4 | 59.1 | 61.4 | 61.7 | 61.4 | 61.3 | 62.5 |
| | Ratio to | 67% | 67% | 65% | 67% | 68% | 67% | 67% | 68% |
| | Comp. | | | | | | | | |
| | Ex. 6 | | | | | | | | |
| Display device reflection | | 16.2 | 14.6 | 13.6 | 14.7 | 14.7 | 14.6 | 14.7 | 15.1 |
| | Ratio to | 48% | 43% | 40% | 44% | 44% | 43% | 43% | 45% |
| | Comp. | | | | | | | | |
| | Ex. 6 | | | | | | | | |
| Color | NTSC | 100.9% | 98.9% | 97.9% | 98.9% | 98.9% | 98.9% | 98.9% | 98.9% |
| reproducibility | ratio | | | | | | | | |

TABLE 6

| | | Comp. | Comp. | Comp. | Comp. | Comp. | Comp. |
|---|---|---|---|---|---|---|---|
| | | Ex. 1 | Ex. 2 | Ex. 3 | Ex. 4 | Ex. 5 | Ex. 6 |
| UV shielding rate on colored layer | | 92.9% | 92.9% | 92.9% | 92.9% | 7.2% | — |
| Lightfastness | ΔTλ1 | 22.1 | 7.5 | 5.6 | 5.6 | 15.4 | — |
| | ΔTλ2 | 4.8 | 2.2 | 1.8 | 1.5 | 3.5 | — |
| Heat | ΔTλ1 | 29.8 | 10.6 | 8.5 | 8.9 | 21.1 | — |
| resistance | ΔTλ2 | 0.3 | 0.6 | 0.5 | 0.6 | 1.0 | — |
| White mode transmission | | 62.7 | 62.6 | 61.1 | 61.5 | 62.3 | 91.4 |
| | Ratio to | 69% | 68% | 67% | 67% | 68% | 100% |
| | Comp. Ex. 5 | | | | | | |
| Display device reflection | | 15.2 | 15.2 | 14.6 | 14.7 | 15.1 | 33.8 |
| | Ratio to | 45% | 45% | 43% | 44% | 45% | 100% |
| | Comp. Ex. 5 | | | | | | |
| Color | NTSC ratio | 98.5% | 98.5% | 98.9% | 98.9% | 98.9% | 91.7% |
| reproducibility | | | | | | | |

The results of Example 2 and Comparative Example 1 show that the addition of the compound A and the sulfur antioxidant can reduce fading of the colored layer.

The results of Example 2 and Comparative Examples 2 and 3 show that the effect of reducing fading is not sufficient when only the compound A and the sulfur antioxidant are added.

The results of Examples 2 and 4 show that the effect of reducing fading can be further improved by adding a polymer containing a structural unit represented by the formula (ii).

The results of Examples 4 and 5 and Comparative Example 4 show that a good effect of reducing fading can be obtained by setting adding the compound A and the sulfur antioxidant in a ratio within a predetermined range.

The results of Example 4 and Comparative Examples 2 and 3 show that the effect of reducing fading is not sufficient when only the compound A and the sulfur antioxidant are added.

The results of Examples 6 and 7 show that a similar effect of reducing fading can be obtained even when the functional layer includes an antiglare layer.

The results of Example 8 show that a similar effect of reducing fading can be obtained even when the ultraviolet absorbing layer on the colored layer is not a transparent substrate.

The results of Example 8 and Comparative Example 5 show that mixing an ultraviolet absorbing material onto the colored layer does not provide a sufficient effect of reducing fading, and a good effect of reducing fading can be obtained only when an ultraviolet absorbing layer is provided on the colored layer.

The display devices of the Examples, which were each provided with the colored layer of the present invention, were able to reduce surface reflection significantly as compared with the display device of Comparative Example 6 not including the colored layer. In addition, whereas the transmittance is significantly reduced when a circular polarizing plate is used, the display devices of the Examples showed good luminance efficiency as indicated by the evaluation values for white mode transmittance, and also had improved color reproducibility.

Examples 1, 2, and 3 were optically designed to absorb one wavelength, two wavelengths, and two wavelengths and near-infrared region, respectively. The larger the number of absorption regions, the better the reflection property.

An embodiment and Examples of the present invention have so far been described in detail. However, the present invention should not be limited to specific embodiments, but should encompass modifications, combinations, or the like of these embodiments, in the range not departing from the spirit of the present invention.

### INDUSTRIAL APPLICABILITY

The present invention can be applied to a composition for forming a colored layer capable of forming a colored layer that can withstand long-term use without requiring a gas barrier layer.

The present invention can also be applied to an optical film and a display device that can maintain high display quality even when used for a long period of time without requiring a gas barrier layer.

### REFERENCE SIGNS LIST

1, 3, 4, 5, 7, 8 . . . Optical film; 10 . . . Colored layer; 20 . . . Transparent substrate; 30 . . . Functional layer; 31 . . . Low refractive index layer; 32 . . . Hard coat layer, 34 . . . Antiglare layer.

What is claimed is:

1. A composition for forming a colored layer, the composition containing a dye (A), an active energy radiation-curable resin (B), a photoinitiator (C), a solvent (D), and an additive (E), wherein
the dye (A) contains at least one of a first coloring material, a second coloring material, and a third coloring material,
the first coloring material has a wavelength of maximum absorption within a range of 470 to 530 nm, and a full width at half maximum of an absorption spectrum of 15 to 45 nm,
the second coloring material has a wavelength of maximum absorption within a range of 560 to 620 nm, and a full width at half maximum of an absorption spectrum of 15 to 55 nm,
within a wavelength range of 380 to 780 nm, the third coloring material exhibits lowest transmittance in a range of 650 to 780 nm,
the additive (E) includes a compound A represented by formula (i) below and a sulfur antioxidant, and
the compound A has a content of 0.01 to 2 when a content of the sulfur antioxidant is taken as 1.
Chemical Formula 1
[In the above formula (i), each R¹ independently represents any one of an alkyl group, an alkenyl group, an aryl group, a heterocyclic group, R⁹CO—, R¹⁰SO²—, and R¹¹NHCO-(R⁹, R¹⁰, and R¹¹ are each independently any one of an alkyl group, an alkenyl group, an aryl group, and a heterocyclic group). R² and R³ each independently represent a hydrogen atom, a halogen atom, an alkyl group, an alkenyl group, an alkoxy group, or an alkenyloxy group. R⁴ to R⁸ each independently represent a hydrogen atom, an alkyl group, an alkenyl group, or an aryl group.]

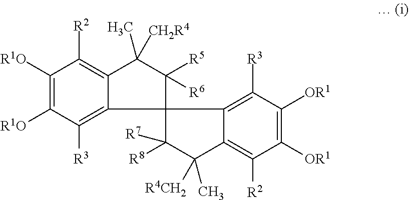

2. The composition for forming the colored layer of claim 1, wherein the sulfur antioxidant is any one of dialkyldithiophosphate, dialkyldithiocarbanate, benzenedithiol, and transition metal complexes thereof.

3. The composition for forming the colored layer of claim 1, wherein the active energy radiation-curable resin (B) is a polymer having a structural unit represented by formula (ii) below.
Chemical Formula 2
[In the formula (ii), R¹² represents a hydrogen atom, halogen atom, carboxyl group, sulfo group, cyano group, hydroxy group, alkyl group having 10 or less carbon atoms, alkoxycarbonyl group having 10 or less carbon atoms, alkylsulfonylaminocarbonyl group having 10 or less carbon atoms, arylsulfonylaminocarbonyl group, alkylsulfonyl group, arylsulfonyl group, acylaminosulfonyl group having 10 or less carbon atoms, alkoxy group having 10 or less carbon atoms, alkylthio group having 10 or less carbon atoms, aryloxy group having 10 or less carbon atoms, nitro group, alkoxycarbonyloxy group, aryloxycarbonyloxy group, acyloxy group having 10 or less carbon atoms, acyl group having 10 or less carbon atoms, carbamoyl group, sulfamoyl group, aryl group having 10 or less carbon atoms, substituted amino group, substituted ureido group, substituted phosphono group, or a heterocyclic group; R¹³ represents a hydrogen atom or an alkyl group having 30 or less carbon atoms; X represents a single bond, an ester group, an aliphatic alkyl chain having 30 or less carbon atoms, an aromatic chain, a polyethylene glycol chain, or a linking group formed by combination thereof; any of R¹², R¹³, and X can contain a spirodioxane ring.]

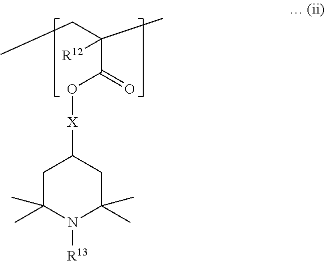

4. The composition for forming the colored layer of claim 1, wherein the dye (A) contains one or more selected from the group consisting of compounds having a porphyrin structure, merocyanine structure, phthalocyanine structure, azo structure, cyanine structure, squarylium structure, coumarin structure, polyene structure, quinone structure, tetradiporphyrin structure, pyrromethene structure, and indigo structure; and a metal complex thereof.

5. An optical film, comprising:
a colored layer that is a cured product of the composition for forming the colored layer according to claim 1;
a transparent substrate located on one surface of the colored layer; and
a functional layer located on the one or the other surface of the colored layer,
wherein one or both of the transparent substrate and the functional layer have an ultraviolet shielding rate of 85% or higher as measured according to a method described in JIS L 1925, and
the functional layer functions as an antireflection layer or an antiglare layer.

6. The optical film of claim 5, further comprising an antistatic layer or a stain-proof layer as the functional layer.

7. A display device comprising the optical film of claim 5.
